(19) United States
(12) Patent Application Publication
(10) Pub. No.: US 2010/0081091 A1
(43) Pub. Date: Apr. 1, 2010

(54) METHOD FOR MANUFACTURING SEMICONDUCTOR DEVICE

(76) Inventors: Koji HASHIMOTO, Yokohama-shi (JP); Daisuke Kawamura, Matsudo-shi (JP); Kentaro Matsunaga, Kawasaki-shi (JP); Iwao Higashikawa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/556,425

(22) Filed: Sep. 9, 2009

(30) Foreign Application Priority Data
Sep. 30, 2008 (JP) P2008-255637

(51) Int. Cl. G03F 7/20

(52) U.S. Cl. 430/311

(57) ABSTRACT

According to an aspect of the present invention, there is provided a method for manufacturing a semiconductor device, the method including; sequentially forming a first film and a second film on a base film; processing the second film, thereby forming a second pattern; processing the first film with the second pattern, thereby forming a first pattern; removing the second pattern; depositing a third film on the base film and the first pattern; processing the third film, thereby forming a third pattern on side walls of the first pattern; removing the first pattern; and processing the base film with the third pattern; wherein, when processing the third film, a process condition is adjusted based on at least one information of a size of the second pattern and a size of the first pattern.

### CROSS-REFERENCE TO RELATED APPLICATIONS

This application claims priority from Japanese Patent Application No. 2008-255637 filed on Sep. 30, 2008, the entire contents of which are incorporated herein by reference.

### BACKGROUND OF THE INVENTION

1. Field of the Invention

An aspect of the present invention relates to a method for manufacturing a semiconductor device.

2. Description of the Related Art

To achieve a fine wiring pattern structure in a semiconductor integrated circuit, for example, there has been proposed a pattern forming method in which side wall patterns are formed on side walls of core patterns formed on a target film and in which the target film is processed with the side wall patterns or patterns embedded in between the side wall patterns as a mask to form wiring patterns, gate electrodes, etc. (e.g. see U.S. Pat. No. 6,063,698).

However, in the pattern forming method, space size of the side wall patterns varies in accordance with variations in size of the core patterns formed on the target film. As a result, there arises a problem that size of wiring patterns, gate electrodes, etc. formed by processing the target film varies. When pattern size or the like varies as described above, reliability of the semiconductor device may be lowered, for example, because of variations in inter-wiring capacitance.

### SUMMARY OF THE INVENTION

According to an aspect of the present invention, there is provided a method for manufacturing a semiconductor device, the method including: sequentially forming a first film and a second film on a base film; processing the second film, thereby forming a second pattern; processing the first film with the second pattern as a mask, thereby forming a first pattern; removing the second pattern; depositing a third film on the base film and the first pattern; processing the third film, thereby forming a third side wall pattern on side walls of the first pattern; removing the first pattern; and processing the base film with the third side wall pattern as a mask, thereby forming a target pattern; wherein, in the step of processing the third film, a process condition is adjusted based on at least one information of a size of the second pattern and a size of the first pattern.

According to another aspect of the present invention, there is provided a method for manufacturing a semiconductor device, the method including: sequentially forming a first film and a second film on a base film; processing the second film, thereby forming a second pattern; processing the first film with the second pattern as a mask, thereby forming a first pattern, removing the second pattern; depositing a third film on the base film and the first pattern; processing the third film, thereby forming a third side wall pattern on side walls of the first pattern; embedding a fourth pattern between the third side wall patterns on the base film; removing the third side wall patterns; and processing the base film with the first and fourth patterns as a mask, thereby forming a target pattern; wherein, in the step of processing the third film, a process condition is adjusted based on at least one information a size of the second pattern and a size of the first pattern.

### BRIEF DESCRIPTION OF THE DRAWINGS

FIGS. 1A to 1H illustrate steps of a semiconductor device manufacturing method according to Embodiment 1 of the invention.

FIG. 2 illustrates patterns formed by a semiconductor device manufacturing method according to the related art.

FIGS. 3A to 3F illustrate steps of a semiconductor device manufacturing method according to Embodiment 2 of the invention.

FIG. 4 illustrates patterns formed by another semiconductor device manufacturing method according to the related art.

### DETAILED DESCRIPTION OF THE INVENTION

Embodiments of the invention will be described below in detail with reference to the drawings.

### Embodiment 1

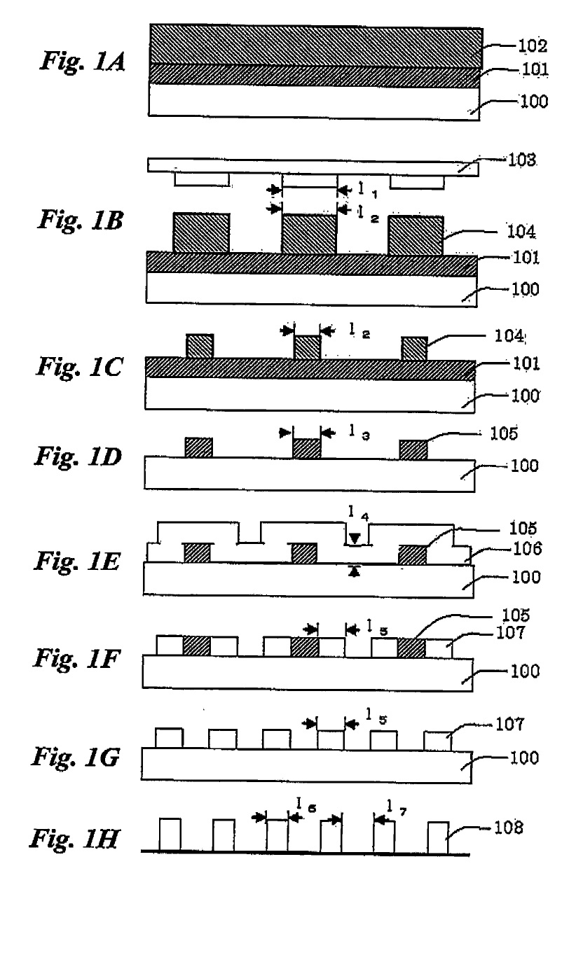

A semiconductor device manufacturing method according to Embodiment 1 of the invention will be described first with reference to FIGS. 1A to 1H. FIGS. 1A to 1H are sectional views illustrating steps of the semiconductor device manufacturing method according to this embodiment.

As shown in FIG. 1A, a gate oxide film (not shown) such as a silicon oxide film, a base film 100 such as a polysilicon film for forming gate electrodes and a first film 101 such as a silicon nitride film are deposited successively on a semiconductor substrate (not shown) of single crystal silicon by a CVD (Chemical Vapor Deposition) method or the like. A second film 102 such as a resist film 102 is formed on the first film 101 in a coating manner. The first film 101 may be formed of plural material layers.

Then, as shown in FIG. 1B, mask patterns formed in an exposure mask 103 are transferred onto the resist film 102 by photolithography, and the resist patterns 104 (second patterns 104) is formed on the first film 101 by processing (developing) the resist film. Before the aforementioned process is performed, the mask pattern size l₁ 1 of the exposure mask 103 is measured. For example, when the exposure mask 103 has line-shaped patterns, the minor axis dimension (width) of each pattern is measured before the aforementioned process is performed. A process condition such as an exposure amount, a focus value, etc. in photolithography is determined based on the measured mask pattern size l₁.

For example, when the mask pattern size l₁ is larger than a desired value, the exposure amount is set to be smaller than the set condition. For example, when the mask pattern size l₁ is smaller than the desired value, the exposure amount is set to be larger than the set condition. In this manner, the process condition is adjusted so that the resist patterns 104 have a desired size. Accordingly, if the measured mask pattern size l₁ is different from a design size, by appropriately adjusting the exposure amount, etc. in accordance with the error 1S between the measured and design sizes, the size of the resist patterns 104 can be approached to the design size.

On this occasion, the size l₂ of the resist patterns 104 formed by photolithography is measured. For example, when the resist patterns 104 are line-shaped patterns, the minor axis dimension (width) of each pattern or the pitch of the resist patterns 104 is measured. In this manner, whether or not the size of the resist patterns 104 is equal to the design size can be checked. For example, in this embodiment, the pattern pitch of the resist patterns 104 is about twice as much as the pitch of the finally-formed gate patterns. For example, when forming gate patterns with a gate width of 45 nm, the pitch of the gate patterns is 90 nm and the pattern pitch size of the resist patterns 104 is about 180 nm.

Then, as shown in FIG. 1C, the resist patterns 104 are slimmed by etching. As the etching, for example, a CDE (Chemical Dry Etching) method, a wet etching method, and an RIE (Reactive Ion Etching) method for an antireflection film (not shown) on the resist film 102 are used. An etching condition is determined based on the desired slimming amount, the type/concentration/pressure of an etching gas, the type/concentration of an etching solution, the material of the resist patterns, the material of the antireflection film, the material of the base film, etc.

The etching condition (process condition) in slimming such as the type of the etching gas, the pressure of the etching gas, discharge power in etching, the slimming amount, the etching rate, etc. is determined based on the difference between the measured resist pattern size l₂ and the design size. For example, when the resist pattern size l₂ is larger than the set value, the slimming amount is set to be larger than the ordinary value. For example, when the resist pattern size l₂ is formed to be smaller than the set value, the slimming amount is set to be smaller than the ordinary value. In this manner, the process condition is adjusted suitably. If the measured resist pattern size l₂ is different from the design pattern size, by appropriately adjusting the process condition in slimming based on the error between the measured size and the design size, the size of the resist patterns 104 can be approached to the design pattern size.

After slimming, the resist pattern size l₂ is measured. In this embodiment, the pattern width l₂ of the resist patterns 104 after slimming is substantially equal to the space width of the finally-formed gate patterns. For example, when forming periodic gate patterns with 30 nm-wide spaces, the size of the resist patterns 104 formed after slimming is set to be 30 nm.

Then, as shown in FIG. 1D, the first film 101 is etched by RIE or the like with the slimmed resist patterns 104 thereon as a mask to thereby form first patterns 105 on the base film 100. A process condition in etching such as the amount of etching, the type of an etching gas, the pressure of the etching gas, discharge power in etching, the etching rate, etc. is determined based on at least one of the measured resist pattern sizes l₂ before and after slimming. For example, when each resist pattern size l₂ is larger than the desired size, the etching time is set to be longer than the set condition. For example, when each resist pattern size l₂ is smaller than the desired size, the etching time is set to be shorter than the set condition. In this manner, the process condition is adjusted suitably. If the measured sizes l₂ of the resist patterns 104 before and after slimming are different from the design pattern size, by suitably adjusting the process condition based on the error between the measured size and the design size, the size l₃ of the first patterns 105 can be approached to a design size.

In this embodiment, the resist patterns 104 are subjected to slimming. However, the first patterns 105 may be subjected to slimming after formation of the first patterns 105 if necessary. In this case, for example, when a silicon nitride film is used for the first patterns 105, the first patterns 105 can be subjected to slimming by wet etching with hot phosphoric acid. When the first patterns 105 are to be subjected to slimming, a condition for slimming the first patterns 105 is adjusted so that the first pattern size approaches a design size. And, the size l₃ after slimming is measured and checked.

After the first film 101 is processed, the resist film 102 is removed by an ashing process (O₂ asher) or the like in an oxygen atmosphere. After removing the resist film 102, the first pattern size l₃ is measured and checked.

Then, as shown in FIG. 1E, a third film 106 is deposited on the first patterns 105 and the base film 100 by a CVD method or the like. As the third film 106, an oxide film, a nitride film, etc., which has etching selectivity with respect to the first film 101 and the base film 100, can be used.

On this occasion, a process condition in deposition of the third film 106 such as the type of a material gas, the set deposited film thickness of the third film 106, etc. is adjusted so that the third film 106 has a desired film thickness. On the other hand, the deposited film thickness l₄ of the deposited third film 106 is measured so that the difference between the measured film thickness l₄ and the desired set film thickness is checked.

By processing the third film 106, the third side wall patterns 107 are formed. The size of the third side wall patterns 107 is substantially equal to the deposition thickness of the third film 106 and to the gate size of the finally-formed gate patterns. A process condition in deposition of the third film 106 such as the type of a material gas, the set deposited film thickness of the third film 106, etc. may be adjusted based on the measured resist pattern sizes l₂ of the resist patterns 104 before and after slimming and the measured size l₃ of the first patterns 105 after etching. For example, when the resist pattern size l₂ before slimming is larger than the set value, the deposited film thickness is set to be larger than the set value. For example, when the resist pattern size l₂ before slimming is smaller than the set value, the deposited film thickness is set to be smaller than the set value. Similarly, for example, when the resist pattern size l₂ after slimming is larger than the set value, the deposited film thickness is set to be larger than the set value. For example, when the resist pattern size l₂ after slimming is smaller than the set value, the deposited film thickness is set to be smaller than the set value. Further, for example, when the first pattern size l₃ after etching is larger than the set value, the deposited film thickness is set to be larger than the set value. For example, when the first pattern size l₃ after etching is smaller than the set value, the deposited film thickness is set to be smaller than the set value. In this manner, the process condition is adjusted suitably.

Then, as shown in FIG. 1F, the third film 106 formed on the first patterns 105 and the base film 100 is removed by etching such as RIE to thereby form third side wall patterns 107 so that the third film 106 is left only on side walls of the first patterns 105.

On this occasion, a process condition in etching of the third film 106 such as etching time, the type of an etching gas, the pressure of the etching gas, discharge power in etching, etc. is determined based on the measured deposited film thickness l₄ of the third film 106. For example, when the deposited film thickness l₄ of the third film 106 is larger than a set film thickness, the etching time is set to be longer than a set time. For example, when the deposited film thickness l₄ of the third film 106 is smaller than the set film thickness, the etching time is set to be shorter than the set time. In this manner, the process condition is adjusted suitably. If the deposited film thickness l₄ of the third film 106 is different from the design film thickness, by appropriately adjusting the process condition based on the error between the measured film thickness and the design film thickness, the size l₅ of the third side wall patterns can be approached to a design pattern size.

Then, as shown in FIG. 1G, the first patterns 105 are removed by etching such as wet etching.

On this occasion, after removing the first patterns 105, the size l₅ such as a pattern width, a pattern diameter, a pattern area, etc. of the side wall patterns 107 is measured. In this embodiment, the size l₅ of the side wall patterns 107 is substantially equal to the gate length of the finally-formed gate patterns.

Then, as shown in FIG. 1H, the base film 100 masked with the third side wall patterns 107 is etched by RIE or the like to thereby form gate patterns 108. Then, the side wall patterns 107 are removed.

A process condition in etching of the base film 100 such as etching times the type of an etching gas, the pressure of the etching gas, discharge power in etching, the etching rate, etc. is determined based on at least one information of the measured deposited film thickness l₄ of the third film 106 and the measured third side wall pattern size l₅. For example, when the deposited film thickness l₄ of the third film 106 is larger than a set film thickness, the etching time is set to be longer than the set condition. For example, when the deposited film thickness l₄ of the third film 106 is smaller than the set film thickness, the etching time is set to be shorter than the set condition. Similarly, when the third side wall pattern size l₅ is larger than a set size, the etching time is set to be longer than the set condition. When the third side wall pattern size l₅ is smaller than the set size, the etching time is set to be shorter than the set condition. In this manner, the process condition is adjusted suitably.

If the deposited film thickness l₄ of the third film 106 or the side wall pattern size l₅ is different from a desired value, by appropriately adjusting the process condition based on the error between the measured value and the design value, the size l₆ of the gate patterns 108 can be approached to a design size.

The semiconductor device manufacturing method according to this embodiment has been described above.

When forming gate patterns by processing the base film 100 masked with the third side wall patterns 107 formed on side walls of the first patterns 105, the gate patterns 108 are formed with use of the side wall patterns 107 as a mask. For this reason, the pattern size of the gate patterns 106 mainly depends on the third side wall pattern size l₅. On the other hand, the space size of the gate patterns 108 mainly depends on the pattern and space sizes of the resist patterns 104 and the pattern and space sizes of the first patterns 105. Accordingly, main causes of variations in the gate pattern size with respect to the design size are variations in the deposited film thickness l₄ of the third film 106 with respect to the design value, variations in the side wall pattern size l₅ in RIE of the third film 106 and in removal of the first patterns 105 between the side wall patterns with respect to the design value and variations in processing of the base film 100. On the other hand, main causes of variations in the gate pattern space size with respect to the design size are not only variations in the deposited film thickness l₄ of the third film 106 with respect to the design value, variations in the side wall pattern size l₅ in RIE of the third film 106 and in removal of the first patterns 105 between the side wall patterns with respect to the design value and variations in processing of the base film 100, but also variations in the mask pattern size l₁ of the exposure mask 103 with respect to the design value, variations in the resist pattern size l₂ before and after slimming with respect to the design value and variations in the first pattern size l₃ in processing of the first film 101 masked with the resist patterns 104 with respect to the design value.

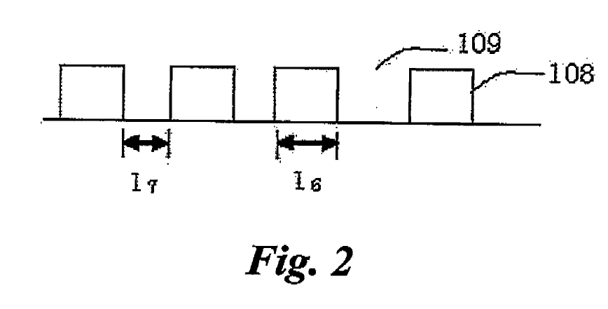

FIG. 2 is a sectional view illustrating gate patterns formed by related-art method using such side wall patterns as a mask. As shown in FIG. 2, in the related-art method, causes of variations in the size l₇ of gate pattern spaces 109 are more significant than causes of variations in the size l₆ of gate patterns 108. Therefore, the variations in the gate pattern space size l₇ with respect to a design size will be larger than the variations in the gate pattern size l₆ with respect to a design size.

On the contrary, in this embodiment, information of pattern sizes, etc. is acquired in respective steps of the manufacturing process shown in FIGS. 1A to 1H so that the gate patterns 108 can be formed finally while the process conditions are determined based on the acquired information. For this reason, in a manufacturing process for forming fine patterns of the semiconductor device, the resist pattern size l₂, etc. are corrected to the design values, and patterns are finally formed with a highly accurate size very close to the design value.

In this embodiment, there is a possibility that variations in the gate pattern space size l₇ will be larger than variations in the gate pattern size l₆. Accordingly, in order to improve a process margin, the gate patterns are designed so that the pattern size is preset to be smaller than the space size. When the gate pattern forming method according to this embodiment is used based on the aforementioned design patterns, desired device performance of the semiconductor device can be kept easily.

In this embodiment, the side pattern size l₅ may be adjusted in such a manner that the size l₅ of the third side wall patterns 107 is measured and the third sidewall patterns 107 are subjected to slimming after the first film 101 is removed in the step shown in FIG. 1G.

On this occasion, a process condition in slimming of the side wall patterns 107 such as etching time, the type of an etching gas, the pressure of the etching gas, discharge power, the slimming amount, the etching rate, etc. is determined based on at least one information of the deposited film thickness l₄ of the third film 106 and the size l₅ of the third side wall patterns 107. For example, when the side wall pattern size l₅ is larger than the design value, the slimming amount is set to be larger than the set condition. For example, when the side wall pattern size l₅ is smaller than the design value, the slimming amount is set to be smaller than the set condition. In this manner, the process condition is adjusted suitably. If the measured size of the side wall patterns 107 is different from the design pattern size, by appropriately adjusting the process condition based on the error between the measured size and the design size, the size of the resist patterns 104 can be approached to a design pattern size.

After slimming, the side wall pattern size may be measured, and an etching condition of etching the base film 100 shown in FIG. 1H may be determined based on the measured size.

By adjusting the side wall pattern size through slimming and by adjusting the etching condition as described above, the size of the gate patterns 108 formed by etching the base film 100 masked with the side wall patterns 107 can be made higher accurate.

### Embodiment 2

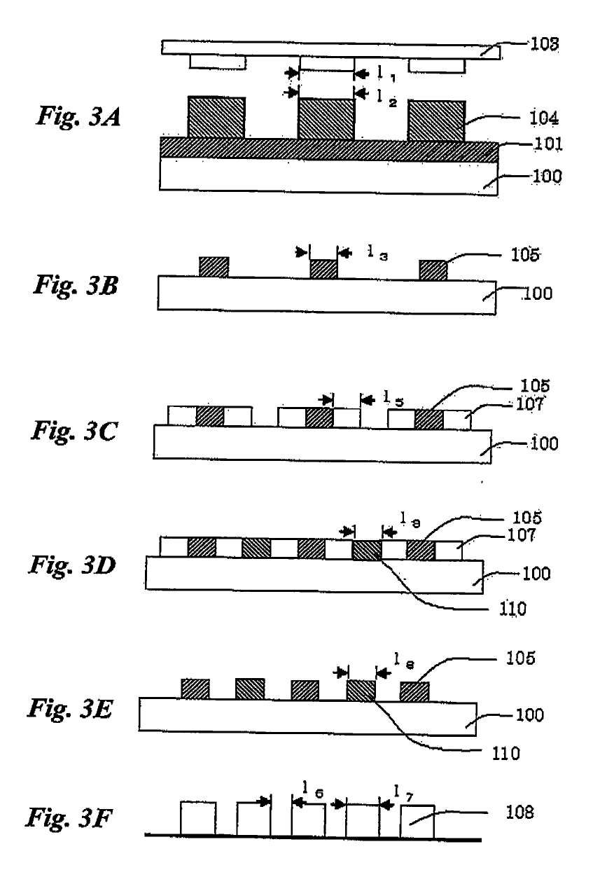

A semiconductor device manufacturing method according to Embodiment 2 of the invention will be described below with reference to FIGS. 3A to 3F. FIGS. 3A to 3F are sectional views illustrating steps of the semiconductor device manufacturing method according to this embodiment.

The method according to Embodiment 2 is different from the method according to Embodiment 1 in that the base layer is processed with the first patterns and the like as a mask. Accordingly, in the following description of this embodiment, parts like those in Embodiment 1 are referred to by like numerals for the sake of convenience.

As shown in FIG. 3A, a base film 100, a first film 101 and a resist film 102 (second film 102) are formed successively on a semiconductor substrate 100. Then, patterns are transferred onto the resist film 102 by photolithography using an exposure mask 103 having mask patterns formed therein, so that resist patterns 104 (second patterns 104) are formed on the first film 101.

Before photolithography, the mask pattern size l₁ of the exposure mask 103 is measured. A process condition in photolithography such as the exposure amount, etc. is adjusted based on the measured result of the mask pattern size l₁. The size l₂ of the resist patterns 104 formed by photolithography is further measured.

Then, as shown in FIG. 3B, the resist patterns 104 are subjected to slimming by etching such as CDE. After slimming, the first film 101 masked with the resist patterns 104 is processed by etching such as RIE to thereby form first patterns 105 on the base film 100.

A process condition in the slimming such as the slimming amount, etc. is determined based on the measured resist pattern size l₂. After slimming, the resist pattern size l₂ is measured. A process condition in etching such as over-etching time, etc. is determined based on at least one information of the measured values of the resist pattern size l₂ before and after slimming. After the resist film 102 is removed, the first pattern size l₃ is further measured.

In this embodiment, the resist patterns 104 are subjected to slimming. However, the first patterns 105 may be subjected to slimming suitably after being formed.

Then, as shown in FIG. 3C, a third film 106 is deposited by a CVD method or the like and processed by etching such as RIE to thereby form third side wall patterns 107 on side walls of the first patterns 105.

On this occasion, a process condition in deposition of the third film 106 such as deposited film thickness, etc. is determined based on at least one information of the measured values of the resist pattern size l₂ before and after slimming and the first pattern size l₃. After the third film 106 is deposited, the film thickness l₄ of the third film 106 is further measured.

On this occasion, a process condition in etching of the third film 106 such as over-etching time, etc. is determined based on the measured deposited film thickness l₄ of the third film 106, similarly to Embodiment 1. After the third film 106 is etched, the size l₅ of the third side wall patterns 107 is further measured.

Then, in this embodiment, as shown in FIG. 3D, a fourth film such as a nitride film is deposited on the base film 100 so as to be embedded in between the third side wall patterns 107 by a CVD method or the like. The fourth film on the side wall patterns 107 and the first patterns 105 is removed by CMP (Chemical Mechanical Polishing) to thereby form fourth patterns 110.

Then, as shown in FIG. 3E, the third side wall patterns 107 are removed by isotropic etching such as CODE or wet etching to thereby reveal the first and fourth patterns 105 and 110 on the base layer 100. After removing the side wall patterns 107, the sizes l₃ and l₈ of the first and fourth patterns are measured.

Then, as shown in FIG. 3F, the base film 100 masked with the first and fourth patterns 105 and 110 is processed by etching such as RIE. Then, the first and fourth patterns 105 and 110 are removed to thereby form gate patterns 108.

A process condition in etching of the base film 100 such as over-etching time, etc. is determined based on the measured film thickness l₄ of the third film 106, the measured size l₅ of the third side wall patterns 107 and the measured sizes l₃ and l₈ of the first and fourth patterns 105 and 110. For example, when the film thickness l₄ of the third film 106 or the side wall pattern size l₅ is larger than a design value, the over-etching time of the base film 100 is set to be shorter than an ordinary value because the fourth pattern size l₈ is smaller than a design size. For example, when the film thickness l₄ of the third film 106 or the third side wall pattern size l₅ is smaller than the design value, the over-etching time is set to be longer than the ordinary value because the fourth pattern size l₈ is larger than the design size. Similarly, when the sizes l₃ and l₈ of the first and fourth patterns 105 and 110 are smaller than design values, the over-etching time of the base film 100 is set to be shorter than the ordinary value. When the sizes l₃ and l₈ of the first and fourth patterns 105 and 110 are larger than the design values, the over-etching time of the base film 100 is set to be longer than the ordinary value. In this manner, the process condition is adjusted.

The semiconductor device manufacturing method according to this embodiment has been described above.

When the base film 100 is processed by use of, as a mask, two kinds of patterns, that is, the first patterns 105 formed on the base film 100 and the fourth patterns 110 formed between the side wall patterns 107 provided on side walls of the first patterns 105, the space size of the gate patterns 108 depends on the size of the side wall patterns 107. On the other hand, the pattern size of the gate patterns 108 depends on the sizes of the first patterns 105 and the fourth patterns 110. For this reason, the space size of the gate patterns 108 mainly depends on the side wall pattern size l₅ whereas the pattern size of the gate patterns 108 mainly depends on the respective sizes of the resist patterns 104, the first and fourth patterns 105 and 110, the resist pattern spaces and the first pattern spaces. That is, main causes of variations in the gate pattern spaces with respect to the design value are variations in the deposited film thickness l₄ of the third film 106 in deposition with respect to the design value and variations in the side wall pattern size l₅ of the side wall patterns 107 in etching with respect to the design value. On the other hand, main causes of variations in the gate pattern size with the design value are not only variations in the deposited film thickness l₄ of the third film 106 with respect to the design value and variations in the side wall pattern size l₅ with respect to the design value but also variations in the mask pattern size l₁ of the exposure mask 103 with respect to the design value, variations in the resist pattern size l₂ in transferring the mask patterns to the resist film 102 with respect to the design value, variations in the resist pattern size l₂ after slimming with respect to the design value and variations in the first pattern size l₃ in processing the first film 101 masked with the resist patterns 104 with respect to the design value.

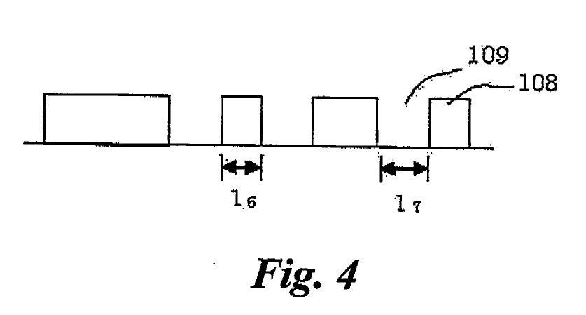

FIG. 4 is a sectional view illustrating gate patterns formed by another related-art method. As shown in FIG. 4, the causes of variations in the size l₆ of the gate patterns 108 are more significant than the causes of variations in the size l₇ of the gate pattern spaces 109. Therefore, variations in the gate pattern size l₆ with respect to the design value will be larger than variations in the gate pattern space size l₇ with respect to the design value.

In this embodiment, information of pattern sizes, etc. is acquired in given steps of the manufacturing process so that process conditions can be determined suitably based on the acquired information. Therefore, in a manufacturing process for forming fine patterns of the semiconductor device, the resist pattern size l₂, etc. are suitably corrected to the design values, and patterns can be finally formed with a highly accurate size very close to the design value.

In this embodiment, the first and fourth pattern sizes l₃ and l₈ may be adjusted in such a manner that the sizes of the first and fourth patterns 105 and 110 are measured and the first and fourth patterns 105 and 110 are subjected to slimming by a CDE method or a wet etching method after the side wall patterns 107 are removed in the step shown in FIG. 3E.

On this occasion, process conditions in slimming of the first and fourth patterns such as the slimming amount, etc. are determined based on the measured first and fourth pattern sizes l₃ and l₈. If the measured sizes l₃ and l₈ of the first and fourth patterns are different from the design pattern sizes, by appropriately adjusting the slimming conditions based on the error between the measured size and the design size, the sizes of the first and fourth patterns 105 and 110 can be approached to the design pattern sizes.

After slimming, the first and fourth pattern sizes l₃ and l₈ may be measured, and an etching condition of etching the base film 100 shown in FIG. 3F may be determined based on the measured sizes.

By adjusting the first and fourth pattern sizes l₃ and l₈ through slimming and by adjusting the etching condition as described above, the size of the gate patterns 108 formed by etching the base film 100 masked with the first and fourth patterns 105 and 110 can be made higher accurate.

In this embodiment, there is a possibility that variations in the size of the gate patterns 108 will be larger than variations in the size of the gate pattern spaces. Accordingly, the gate patterns are designed so that the space size is preset to be larger than the pattern size. As a result, gate patterns 108 with a high process margin and a desired device performance are easily formed.

Although Embodiments 1 and 2 have been described on the method of forming gate patterns 108, not only the gate patterns 108 but also fine holes or fine wiring patterns, especially line-shaped wiring patterns, etc. can be formed according to the invention.

Although Embodiments 1 and 2 have been described in the case where the resist film 102 is used as the second film 102 formed on the first film 101, another film than the resist film 102, such as an organic film having etching selectivity to the first film 101 may be used as the second film 102. In this case, a resist film may be formed on the second film 102, and the second film 102 may be processed by photolithography and RIE to thereby form second patterns 104 on the first film 101.

What is claimed is:

1. A method for manufacturing a semiconductor device, the method comprising:
sequentially forming a first film and a second film on a base film;
processing the second film, thereby forming a second pattern;
processing the first film with the second pattern as a mask, thereby forming a first pattern;
removing the second pattern;
depositing a third film on the base film and the first pattern;
processing the third film, thereby forming a third side wall pattern on side walls of the first pattern;
removing the first pattern; and
processing the base film with the third side wall pattern as a mask, thereby forming a target pattern;
wherein, in the step of processing the third film, a process condition is adjusted based on at least one information of a size of the second pattern and a size of the first pattern.

2. The method according to claim 1, further comprising:
measuring the size of the second pattern.

3. The method according to claim 1, further comprising:
measuring the size of the first pattern.

4. The method according to claim 1,
wherein, in the step of processing the base film, a process condition is adjusted based on at least one information of a deposited film thickness of the third film and a size of the third side wall pattern.

5. The method according to claim 1,
wherein, in the step of depositing the third film, a process condition is adjusted based on at least one information of the size of the second pattern and the size of the first pattern.

6. The method according to claim 1, further comprising:
slimming the third side wall pattern, before processing the base film.

7. The method according to claim 6,
wherein, in the step of slimming the third side wall pattern, a process condition is adjusted based on at least one information of a deposited film thickness of the third film and a size of the third side wall pattern before slimming.

8. The method according to claim 7, further comprising:
measuring the size of the third side wall pattern, after sliming the third side wall pattern and before processing the base film.

9. A method for manufacturing a semiconductor device, the method comprising:
sequentially forming a first film and a second film on a base film;
processing the second film, thereby forming a second pattern;
processing the first film with the second pattern as a mask, thereby forming a first pattern;
removing the second pattern;
depositing a third film on the base film and the first pattern;
processing the third film, thereby forming a third side wall pattern on side walls of the first pattern;
embedding a fourth pattern between the third side wall patterns on the base film;
removing the third side wall patterns; and
processing the base film with the first and fourth patterns as a mask, thereby forming a target pattern;
wherein, in the step of processing the third film, a process condition is adjusted based on at least one information a size of the second pattern and a size of the first pattern.

10. The method according to claim 9, further comprising:
measuring the size of the second pattern.

11. The method according to claim 9, further comprising:
measuring the size of the first pattern.

12. The method according to claim 9,
wherein, in the step of processing the base film a process condition is adjusted based on at least one information of a deposited film thickness of the third film and sizes of the first and fourth patterns.

13. The method according to claim 9,
wherein, in the step of depositing the third film, a process condition is adjusted based on at least one information of the size of the second pattern and the size of the first pattern.

14. The method according to claim 9, further comprising:
slimming the first and fourth patterns, before processing the base film.

15. The method according to claim 14,
wherein, in the step of slimming the first and fourth patterns, a process condition is adjusted based on at least one information of a deposited film thickness of the third film and sizes of the first and fourth patterns before slimming.

16. The method according to claim 15, further comprising:
measuring the sizes of the first and fourth patterns, after sliming the first and fourth patterns and before processing the base film.
